(19) United States
(12) Patent Application Publication
(10) Pub. No.: US 2006/0214227 A1
(43) Pub. Date: Sep. 28, 2006

(54) Semiconductor memory device and method of manufacturing semiconductor memory device

(75) Inventor: Hiroomi Nakajima, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/270,501

(22) Filed: Nov. 10, 2005

(30) Foreign Application Priority Data
Mar. 22, 2005 (JP) 2005-082310

(51) Int. Cl. H01L 27/12

(52) U.S. Cl. 257/347

(57) ABSTRACT

A semiconductor memory device includes an insulation layer provided on a semiconductor substrate; a semiconductor layer provided on the insulation layer; a source layer of a first conductivity type formed in the semiconductor layer; a drain layer of the first conductivity type formed in the semiconductor layer; a body region of the first conductivity type formed in the semiconductor layer between the source layer and the drain layer, the body region being in an electrically floating state and storing data when electric charges are charged into the body region or discharged from the body region; a first gate insulation film formed on the body region; and a first gate electrode formed on the first gate insulation film, wherein the body region is fully depleted when at least data is written into the body region or read from the body region.

### CROSS-REFERENCE TO RELATED APPLICATION

This application is based upon and claims the benefit of priority from the prior Japanese Patent Applications No. 2005-82310, filed on Mar. 22, 2005, the entire contents of which are incorporated herein by reference.

### BACKGROUND OF THE INVENTION

1. Field of the Invention

The present invention relates to a semiconductor memory device and a method of manufacturing the semiconductor memory device.

2. Background Art

A floating body cell (FBC) memory is developed as a memory cell that replaces a dynamic random access memory (DRAM). Further, along with miniaturization of elements, a full-depression type FBC (hereinafter, also referred to as “FD-FBC”) memory is also developed.

Conventionally, the FD-FBC memory is constructed by an N+-type source layer, a P-type body region, and an N+-type drain layer (hereinafter, “N+PN+-type”). In this case, when the concentration of a P-type impurity included in the body region is high, a threshold voltage in the memory cell becomes high. Consequently, the current driving force in the memory cell decreases, and the working speed of the memory cell becomes low at the time of reading/writing data.

### SUMMARY OF THE INVENTION

A semiconductor memory device according to an embodiment of the present invention comprises a semiconductor substrate; an insulation layer provided on the semiconductor substrate; a semiconductor layer provided on the insulation layer; a source layer of a first conductivity type formed in the semiconductor layer; a drain layer of the first conductivity type formed in the semiconductor layer; a body region of the first conductivity type formed in the semiconductor layer between the source layer and the drain layer, the body region being in an electrically floating state and storing data when electric charges are charged into the body region or discharged from the body region; a first gate insulation film formed on the body region; and a first gate electrode formed on the first gate insulation film, wherein

the body region is fully depleted when at least data is written into the body region or read from the body region.

A method of manufacturing a semiconductor memory device comprises preparing a SOI substrate according to an embodiment of the present invention, the SOI substrate including a semiconductor substrate of a first conductivity type, an insulation layer provided on the semiconductor substrate, and a semiconductor layer of the first conductivity type provided on the insulation layer; forming a gate insulation film on the semiconductor layer; forming a gate electrode on the gate insulation film; and forming a source layer of the first conductivity type and a drain layer of the first conductivity type reaching the insulation layer by implanting impurities of the first conductivity type into the semiconductor layer, wherein

the conductivity type of the semiconductor layer between the source layer and the drain layer is maintained in the first conductivity type.

A method of manufacturing a semiconductor memory device comprises preparing a SOI substrate according to an embodiment of the present invention, the SOI substrate including a semiconductor substrate of a second conductivity type, an insulation layer provided on the semiconductor substrate, and a semiconductor layer of the second conductivity type provided on the insulation layer; changing the conductivity type of the semiconductor layer and the semiconductor substrate, which are located adjacent to the insulation layer, to a first conductivity type by implanting impurities of a first conductivity type, so that the impurities go through the semiconductor layer and the insulation layer to reach the semiconductor substrate; forming a gate insulation film on the semiconductor layer; forming a gate electrode on the gate insulation film; forming a source layer of the first conductivity type and a drain layer of the first conductivity type by implanting impurities of the first conductivity type in the semiconductor layer.

### BRIEF DESCRIPTION OF THE DRAWINGS

FIG. 1 to FIG. 4 are cross-sectional flow diagrams showing a method of manufacturing an FD-FBC memory according to a first embodiment of the present invention; and

FIG. 5 to FIG. 7 are cross-sectional flow diagrams showing a method of manufacturing an FD-FBC memory according to a second embodiment of the present invention.

### DETAILED DESCRIPTION OF THE INVENTION

Exemplary embodiments of the present invention will be explained below with reference to the accompanying drawings. The embodiments do not limit the present invention. In the following embodiments, the effects of the present invention are not lost when a P-type semiconductor is used in place of an N-type semiconductor and also when an N-type semiconductor is used in place of a P-type semiconductor.

### First Embodiment

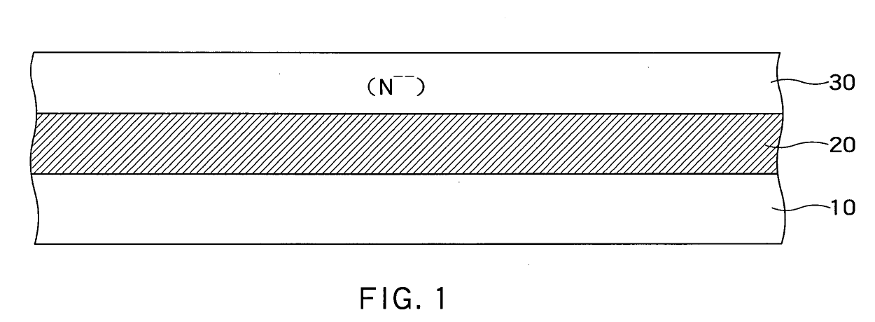

FIG. 1 to FIG. 4 are cross-sectional flow diagrams showing a method of manufacturing an FD-FBC memory according to a first embodiment of the present invention. First, as shown in FIG. 1, a silicon-on-insulator (SOI) substrate is prepared. The SOI substrate includes a semiconductor substrate 10, an insulation layer (hereinafter, also referred to as a “BOX layer”) 20 provided on the semiconductor substrate 10, and a semiconductor layer (hereinafter, also referred to as an “SOI layer”) 30 provided on the BOX layer 20. The semiconductor substrate 10 is an N-type silicon substrate or an N-type GaAs substrate, for example. The BOX layer 20 consists of a silicon oxide film, for example. A thickness of the BOX layer 20 is 30 nm or below, for example. The SOI layer 30 consists of N-type silicon, for example. A thickness of the SOI layer 30 is 50 nm or below, for example. Impurity concentration in the SOI layer 30 is 1×10¹⁷ cm⁻³ or below, for example.

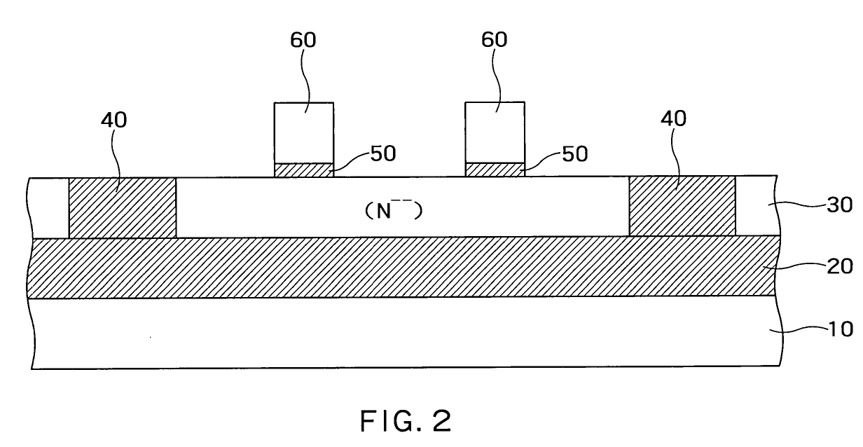

Next, as shown in FIG. 2, a shallow trench isolation (STI) 40 is formed in an element isolation region. To form the STI 40, first, the SOI layer 30 other than the element formation region is removed using a photolithography technique and reactive ion etching (RIE), thereby forming a trench. An insulation film such as a silicon oxide film is filled in the trench.

A material of gate insulation film 50 is then formed on the SOI layer 30. A material of gate electrode 60 is deposited on this SOI layer 30. The material of gate insulation film 50 consists of a silicon oxide film, for example, and has a thickness of 10 nm, for example. The material of gate electrode 60 consists of polysilicon, for example, and has a thickness of 300 nm, for example.

The material of gate electrode 60 and the material of gate insulation film 50 are then etched using the photolithography technique and the reactive ion etching (RIE). As a result, a gate electrode 60 and a gate insulation film 50 are formed. It should be noted that a channel ion is not implanted before the gate insulation film 50 and the gate electrode 60 are formed.

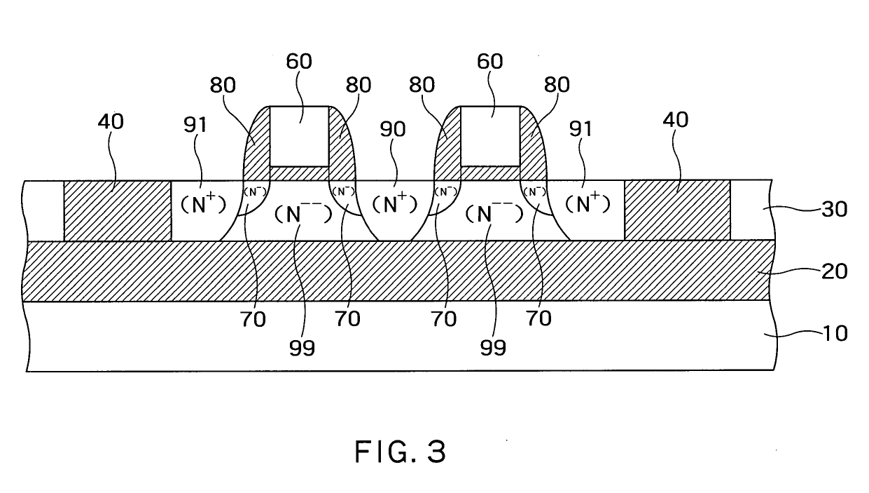

Next, as shown in FIG. 3, an N-type impurity (for example, arsenic or phosphorus) is ion implanted into the SOI layers 30 at both sides of the gate electrode 60. As a result, a lightly diffused drain (LDD) region 70 is formed. Impurity concentration in the LDD region is 10¹⁸ cm⁻³, for example.

A silicon oxide film is then deposited on the entire surface of the substrate. This silicon oxide film is etched by the RIE method. As a result, a sidewall oxide film 80 is remained on the sidewall of the gate electrode 60. An N-type impurity (for example, arsenic or phosphorus) is ion implanted to both sides of the gate electrode 60 using the sidewall oxide film 80 as a mask. After the ion implantation, the substrate is heat treated to activate the impurity, and the impurity diffusion layer reaches the BOX layer 20 from the surface of the SOI layer 30. As a result, a source layer 90 and a drain layer 91 are formed. Impurity concentration in the source layer and the drain layer is higher than the impurity concentration in a body region 99. Impurity concentration in the source layer and the drain layer is 10²⁰ cm⁻³, for example. Since the source layer 90 and the drain layer 91 reach the BOX layer 20 from the surface of the SOI layer 30, the body region 99 is formed between the source layer 90 and the drain layer 91.

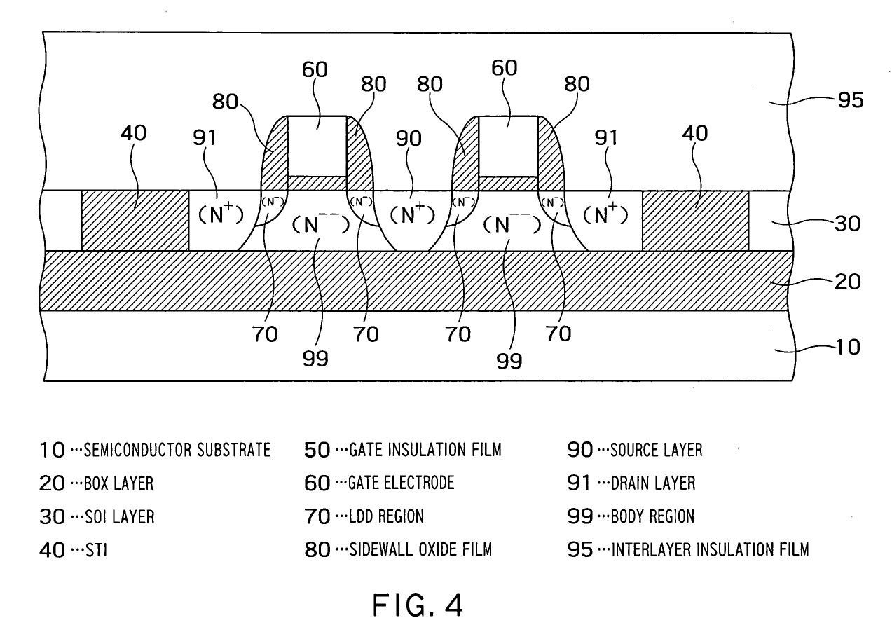

Next, as shown in FIG. 4, an interlayer insulation film 95 is deposited on the substrate by using a low pressure-chemical vapor deposition (LP-CVD) method or the like. The interlayer insulation film 95 is a silicon oxide film, for example, and has a thickness of 600 nm, for example. Next, a contact hole (not shown) is provided on the interlayer insulation film 95, and an electrode material is filled into the contact hole. Thereafter, an FBC memory is completed using a known method.

The thickness of the BOX layer 20 is 30 nm or below. Further, the thickness of the SOI layer 30 is 50 nm or below, and the impurity concentration in the SOI layer 30 is 1×10¹⁷ cm⁻³ or below. Therefore, a part of the semiconductor substrate 10 which is located adjacent to the BOX layer 20 functions as a second gate electrode (back gate electrode), and the body region 99 can be fully depleted.

According to the manufacturing method of the first embodiment, a part of the SOI layer 30 is used as the body region 99 (channel region), without carrying out a channel ion implantation. Therefore, according to the first embodiment, the number of manufacturing steps is smaller than that according to the conventional technique. As a result, a cycle time in the manufacturing of the semiconductor device can be shortened, thereby decreasing the cost of the semiconductor device.

Further, according to the manufacturing method in the first embodiment, the FD-FBC memory having the N⁺-type source layer 90, the N-type body region 99, and the N⁺-type drain layer 91 (hereinafter, referred to as an “N⁺NN⁺-type”) is formed. Since the source layer 90 and the drain layer 91 are diffused from the surface of the SOI layer 30 to the BOX layer 20, the body region 99 is in an electrically floating state. When data is written into or read from this FD-FBC memory, the body region is fully depleted. Therefore, in the FD-FBC, the conductivity type of the body region 99 (channel region) does not need to be set opposite to the conductivity type of the source layer 90 and the drain layer 91. In other words, when the impurity concentration is sufficiently low (1×10¹⁷ cm⁻³ or below) to allow the body region to be easily depleted, the conductivity type of the body region 99 can be the same as that of the source layer 90 and the drain layer 91. In this case, since the conductivity type of the body region 99 is the same as the conductivity type of the source layer 90 and the drain layer 91, the threshold voltage of the FD-FBC memory becomes lower than the conventional threshold voltage. When the threshold voltage becomes low, the writing current of data “1” increases. A current that passes through between the source and the body or between the drain and the body is larger in the N⁺NN⁺-type memory cell than in the N⁺PN⁺-type memory cell. As a result, according to the FD-FBC memory in the present embodiment, the working speed of the memory cell at the data writing/reading time is faster than that according to the conventional memory cell.

When the conductivity type of the body region 99 is set the same as the conductivity type of the source layer 90 and the drain layer 91, a current leakage may occur when the FD-FBC memory is off. However, since the body region 99 is in a fully depleted state during a data holding time not only during the writing/reading time, a current leakage does not occur. The N⁺NN⁺-type memory cell has no built-in potential between the base layer/drain layer and the channel as compared with the N⁺PN⁺-type memory cell. Therefore, the electric field at the edge of the source layer/drain layer is mitigated accordingly, and data holding characteristics are improved.

### Second Embodiment

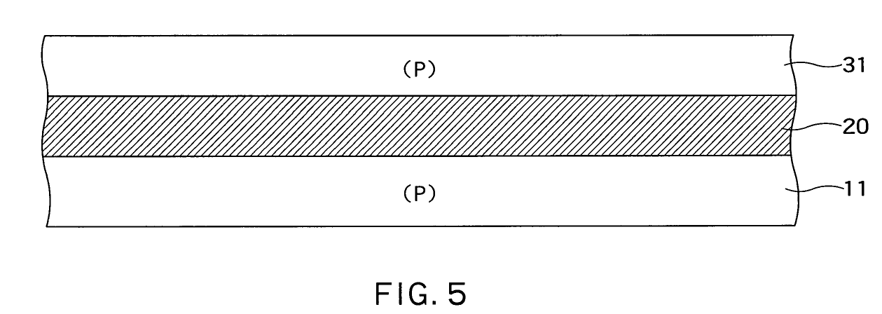

FIG. 5 to FIG. 7 are cross-sectional flow diagrams showing a flow of a method of manufacturing an FD-FBC memory according to a second embodiment of the present invention. Constituent elements similar to those according to the first embodiment are designated by like reference numerals.

As shown in FIG. 5, a silicon-on-insulator (SOI) substrate is prepared first. The SOI substrate includes a semiconductor substrate 11, the BOX layer 20 provided on the semiconductor substrate 11, and the SOI layer 31 provided on the BOX layer 20. The semiconductor substrate 11 is a P-type silicon substrate or a P-type GaAs substrate. The SOI layer 31 consists of P-type silicon. A thickness of the SOI layer 31 is 50 nm or below, for example. Impurity concentration in the SOI layer 31 is 1×10¹⁷ cm⁻³ or below, for example.

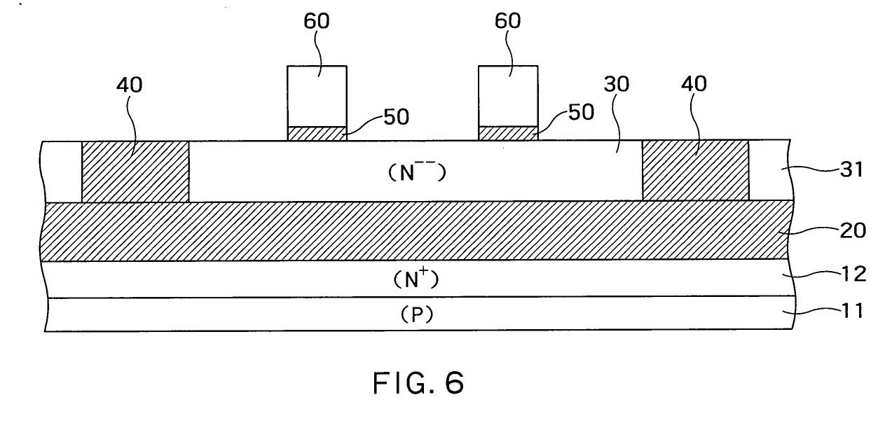

Thereafter, as shown in FIG. 6, the STI 40 is formed using a method similar to that according to the first embodiment. An N-type impurity (arsenic or phosphorus, for example) is ion implanted to reach the semiconductor substrate 11 passing through the SOI layer 31 and the BOX layer 20. With this arrangement, a region adjacent to the BOX layer 20 in the semiconductor substrate 11 and the SOI layer 31 are changed to the N-type semiconductor. The N-type semiconductor region adjacent to the BOX layer 20 in the semiconductor substrate 11 is set as a second gate electrode 12. In this case, impurity implantation energy is set such that the peak of the impurity concentration is equal to or below the interface between the semiconductor substrate 11 and the BOX layer 20. As a result, the N-type impurity concentration in the second gate electrode 12 becomes relatively high, and the N-type impurity concentration in the SOI layer 31 becomes relatively low. For example, the N-type impurity concentration in the second gate electrode 12 is 1×10¹⁹ cm⁻³ or above, and the N-type impurity concentration in the SOI layer 31 is 1×10¹⁷ cm⁻³ or below. The second gate electrode 12 may have low resistance, and it is not necessary to accurately control the N-type impurity concentration in the second gate electrode 12. However, since the N-type impurity concentration in the SOI layer 31 is related to the threshold voltage in the memory cell, this impurity concentration needs to be accurately controlled. The N-type impurity concentration means the concentration of the N-type impurity that is implanted in excess of the P-type impurity.

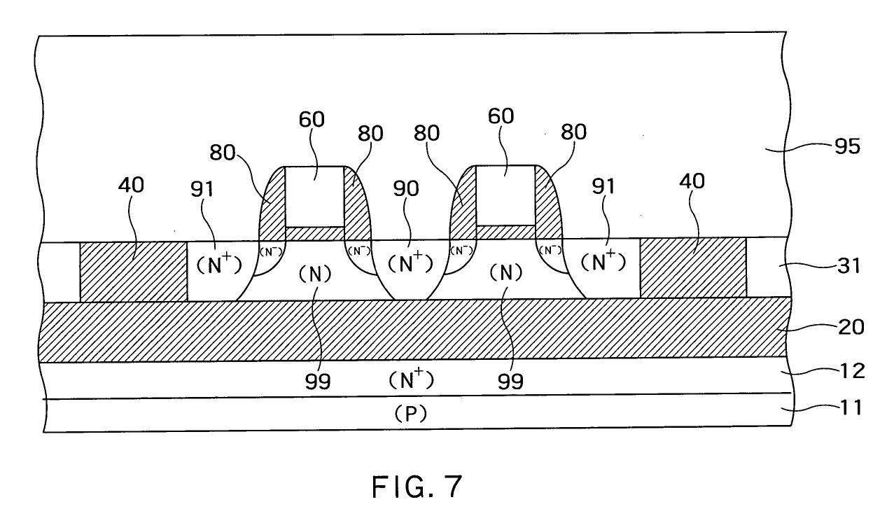

Thereafter, through a process similar to that according to the first embodiment, an FD-FBC memory cell as shown in FIG. 7 is completed. The process shown in FIG. 6 and FIG. 7 is the same as that according to the first embodiment, and therefore, explanation therefor is omitted.

According to the second embodiment, even when a P-type SOI substrate is used, the FD-FBC memory cell of the N⁺NN⁺-type can be manufactured. Further, the manufacturing method according to the second embodiment has effects similar to those of the method according to the first embodiment.

The FD-FBC memories according to the above embodiments can decrease the junction leakage. This is because the body region 99 is in a fully depleted state during the data holding time not only during the writing/reading time.

1. A semiconductor memory device comprising:
a semiconductor substrate;
an insulation layer provided on the semiconductor substrate;
a semiconductor layer provided on the insulation layer;
a source layer of a first conductivity type formed in the semiconductor layer;
a drain layer of the first conductivity type formed in the semiconductor layer;
a body region of the first conductivity type formed in the semiconductor layer between the source layer and the drain layer, the body region being in an electrically floating state and storing data when electric charges are charged into the body region or discharged from the body region;
a first gate insulation film formed on the body region; and
a first gate electrode formed on the first gate insulation film, wherein
the body region is fully depleted when at least data is written into the body region or read from the body region.

2. The semiconductor memory device according to claim 1, wherein
an impurity concentration in the body region is lower than that in the source layer and the drain layer.

3. The semiconductor memory device according to claim 1, wherein
a thickness of the body region is 50 nm or below.

4. The semiconductor memory device according to claim 1, wherein
an impurity concentration in the body region is 1×10¹⁷ cm⁻³ or below.

5. The semiconductor memory device according to claim 1, wherein
a region of the semiconductor substrate, which region is located adjacent to the insulation layer, functions as a second gate electrode,
the insulation layer functions a second gate insulation film.

6. The semiconductor memory device according to claim 1, wherein
the source layer, the drain layer, the body region, the gate insulation film and the gate electrode form a memory cell of a FBC memory.

7. The semiconductor memory device according to claim 1, wherein
the semiconductor substrate and the semiconductor layer are the first conductivity type.

8. The semiconductor memory device according to claim 1, wherein
the semiconductor substrate includes a semiconductor substrate layer of the first conductivity type and a semiconductor substrate layer of the second conductivity type,
the semiconductor substrate layer of the first conductivity type is located adjacent to the insulation layer.

9. A method of manufacturing a semiconductor memory device comprising:
preparing a SOI substrate including a semiconductor substrate of a first conductivity type, an insulation layer provided on the semiconductor substrate, and a semiconductor layer of the first conductivity type provided on the insulation layer;
forming a gate insulation film on the semiconductor layer;
forming a gate electrode on the gate insulation film; and
forming a source layer of the first conductivity type and a drain layer of the first conductivity type reaching the insulation layer by implanting impurities of the first conductivity type into the semiconductor layer, wherein
the conductivity type of the semiconductor layer between the source layer and the drain layer is maintained in the first conductivity type.

10. The method of manufacturing a semiconductor memory device according to claim 9, wherein
an impurity concentration of the semiconductor layer between the source layer and the drain layer is lower than that of the source layer and the drain layer.

11. The method of manufacturing a semiconductor memory device according to claim 9, wherein
a thickness of the semiconductor layer is 50 nm or below.

12. The method of manufacturing a semiconductor memory device according to claim 9, wherein
an impurity concentration in the semiconductor layer between the source layer and the drain layer is 1×10¹⁷ cm⁻³ or below.

13. A method of manufacturing a semiconductor memory device comprising:
preparing a SOI substrate including a semiconductor substrate of a second conductivity type, an insulation layer provided on the semiconductor substrate, and a semiconductor layer of the second conductivity type provided on the insulation layer;
changing the conductivity type of the semiconductor layer and the semiconductor substrate, which are located adjacent to the insulation layer, to a first conductivity type by implanting impurities of a first conductivity type, so that the impurities go through the semiconductor layer and the insulation layer to reach the semiconductor substrate;
forming a gate insulation film on the semiconductor layer;
forming a gate electrode on the gate insulation film;
forming a source layer of the first conductivity type and a drain layer of the first conductivity type by implanting impurities of the first conductivity type in the semiconductor layer.

14. The method of manufacturing a semiconductor memory device according to claim 13, wherein
an impurity concentration of the semiconductor layer between the source layer and the drain layer is lower than that of the source layer and the drain layer.

15. The method of manufacturing a semiconductor memory device according to claim 13, wherein
a thickness of the semiconductor layer is 50 nm or below.

16. The method of manufacturing a semiconductor memory device according to claim 13, wherein
an impurity concentration of the first conductivity type in the semiconductor layer between the source layer and the drain layer is 1×10¹⁷ cm⁻³ or below.
